(19) United States
(12) Patent Application Publication
(10) Pub. No.: US 2005/0167788 A1
(43) Pub. Date: Aug. 4, 2005

(54) Semiconductor device and method of manufacturing same

(75) Inventor: Isao Matsumoto, Kyoto (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Semiconductor Leading Edge Technologies, Inc., Tsukuba-shi (JP)

(21) Appl. No.: 11/023,416

(22) Filed: Dec. 29, 2004

(30) Foreign Application Priority Data
Jan. 29, 2004 (JP) 2004-021654

(51) Int. Cl. H01L 27/01

(52) U.S. Cl. 257/635

(57) ABSTRACT

A semiconductor device comprises: a substrate; a first film provided on the substrate; an insulation layer made of low-k material provided on the first film; a protection layer provided on a sidewall of a hole penetrating through the insulation layer and the first film to the substrate to cover the insulation layer, and a conducting portion filling the hole. The protection layer is more compact than the low-k material.

### CROSS-REFERENCE TO RELATED APPLICATIONS

This application is based upon and claims the benefit of priority from the prior Japanese Patent Application No. 2004-021654, filed on Jan. 29, 2004; the entire contents of which are incorporated herein by reference.

### BACKGROUND OF THE INVENTION

The invention relates to a semiconductor device and a method of manufacturing the same, and more particularly, to a semiconductor device with an interlayer insulating structure using low-k insulating film and a method of manufacturing the same.

Metallic wiring in a semiconductor integrated circuit has encountered a significant problem of signal delay due to the increase of wiring resistance and interwiring capacitance as the wiring pitch decreases. To solve this, the reduction of dielectric constant of the interlayer isolation film provided between the wirings is indispensable (see, e.g., Japanese Laid-Open Patent Application H11-97533 (1999)). For example, the effective relative dielectric constant required for interlayer insulating film compliant with the next-generation 65-nanometer technology node is supposed to be 2.2 to 2.7.

However, since the low-k (low dielectric constant) film is often formed as porous material, it does not have sufficient physical and chemical durability, which causes a problem that it is susceptible to damage from plasma and various drug solution during the manufacturing process. Hence the process is designed to form another film on both sides of the low-k film to protect it from being exposed.

However, when a pattern including holes has been formed in the low-k film, its sidewall will inevitably be exposed. Direct exposure of the sidewall to drug solution or post-process plasma after the etching of such holes in the low-k film causes a problem that the low-k film is damaged by the distortion of its pattern shape or water penetration. In particular, this problem significantly occurs for the low-k film into which pores are introduced for reducing its dielectric constant.

### SUMMARY OF THE INVENTION

According to an aspect of the invention, there is provided a semiconductor device comprising: a substrate; a first film provided on the substrate; an insulation layer made of low-k material provided on the first film; a protection layer provided on a sidewall of a hole penetrating through the insulation layer and the first film to the substrate to cover the insulation layer, the protection layer being more compact than the low-k material; and a conducting portion filling the hole.

The protection layer may be formed to cover the insulation layer of the sidewall of the hole by sputtering the first film with plasma when the first film appears at the bottom of the hole before the hole is allowed to penetrate through the insulation layer and the first film to the substrate.

The semiconductor device may further comprises a second film provided on the insulation layer and formed from the same kind of material as the first film.

The first film may comprise as a main ingredient at least one selected from the group consisting of silicon oxide (SiOₓ), silicon nitride (SiNₓ), silicon carbide (SiCₓ), silicon carboxide (SiCₓO_{y}), silicon oxinitride (SiOₓN_{y}), and silicon carbonitride (SiCₓN_{y}).

The low-k material may comprise as a main ingredient at least one selected from the group consisting of silicon oxides having one or more methyl groups, silicon oxides having one or more hydrogen groups, and organic polymers.

According to other aspect of the invention, there is provided a semiconductor device comprising: a substrate; a first film provided on the substrate; an insulation layer made of low-k material provided on the first film; a protection layer provided on a sidewall of a hole penetrating through the insulation layer and the first film to the substrate to cover the insulation layer, the protection layer containing. one or more elements that are included in the first film but are not included in the low-k material; and a conducting portion filling the hole.

The protection layer may be formed to cover the insulation layer of the sidewall of the hole by sputtering the first film with plasma when the first film appears at the bottom of the hole before the hole is allowed to penetrate through the insulation layer and the first film to the substrate.

The semiconductor device may further comprise a second film provided on the insulation layer and formed from the same kind of material as the first film.

The first film may comprise as a main ingredient at least one selected from the group consisting of silicon oxide (SiOₓ), silicon nitride (SiNₓ), silicon carbide (SiCₓ), silicon carboxide (SiCₓO_{y}), silicon oxinitride (SiOₓN_{y}), and silicon carbonitride (SiCₓN_{y}).

The low-k material may comprise as a main ingredient at least one selected from the group consisting of silicon oxides having one or more methyl groups, silicon oxides having one or more hydrogen groups, and organic polymers.

According to other aspect of the invention, there is provided a method of manufacturing a semiconductor device comprising the steps of: forming a first film on a substrate; forming an insulation layer made of low-k material on the first film; forming a hole penetrating through the insulation layer to the first film; sputtering the first film exposed at the bottom of the hole with plasma to form a protection layer on a sidewall of the hole; and filling the hole with conductive material.

The plasma may be formed using at least one gas selected from the group consisting of argon (Ar), hydrogen (H₂), and nitrogen (N₂).

The first film may comprise as a main ingredient at least one selected from the group consisting of silicon oxide (SiOₓ), silicon nitride (SiNₓ), silicon carbide (SiCₓ), silicon carboxide (SiCₓO_{y}), silicon oxinitride (SiOₓN_{y}), and silicon carbonitride (SiCₓN_{y}).

The low-k material may comprise as a main ingredient at least one selected from the group consisting of silicon oxides having one or more methyl groups, silicon oxides having one or more hydrogen groups, and organic polymers.

The protection layer may be more compact than the low-k material.

According to other aspect of the invention, there is provided a method of manufacturing a semiconductor device comprising the steps of: forming a first film on a substrate; forming an insulation layer made of low-k material on the first film; forming a second film on the insulation layer; forming a hole penetrating through the second film and the insulation layer to the first film; sputtering the first film exposed at the bottom of the hole with plasma to form a protection layer on a sidewall of the hole; and filling the hole with conductive material.

The second film may be made of the same kind of material as the first film.

The plasma may be formed using at least one gas selected from the group consisting of argon (Ar), hydrogen (H₂), and nitrogen (N₂).

The first film may comprise as a main ingredient at least one selected from the group consisting of silicon oxide (SiOₓ), silicon nitride (SiNₓ), silicon carbide (SiCₓ), silicon carboxide (SiCₓO_{y}), silicon oxinitride (SiOₓN_{y}), and silicon carbonitride (SiCₓN_{y}).

The low-k material may comprise as a main ingredient at least one selected from the group consisting of silicon oxides having one or more methyl groups, silicon oxides having one or more hydrogen groups, and organic polymers.

Note that the term “low dielectric constant material” as used in this specification means materials having relative dielectric constants lower than that of conventional silicon oxide (SiO₂), and more specifically, means materials having relative dielectric constants lower than 4.

### BRIEF DESCRIPTION OF THE DRAWINGS

The present invention will be understood more fully from the detailed description given herebelow and from the accompanying drawings of the embodiments of the invention. However, the drawings are not intended to imply limitation of the invention to a specific embodiment, but are for explanation and understanding only.

In the drawings:

FIG. 1 is a schematic view illustrating a cross-sectional structure of a relevant part of a semiconductor device according to an embodiment of the invention;

FIG. 2 is a flow chart showing a relevant part of a method of manufacturing a semiconductor device according to an embodiment of the invention;

FIGS. 3A through 3C are process cross-sectional views showing a relevant part of a manufacturing method according to an embodiment of the invention;

FIGS. 4A through 4C are process cross-sectional views showing a relevant part of a manufacturing method according to an embodiment of the invention;

FIGS. 5A through 5C are process cross-sectional views showing a method of manufacturing a semiconductor device according to an example of the invention;

FIGS. 6A and 6B are process cross-sectional views showing a method of manufacturing a semiconductor device according to an example of the invention;

FIGS. 7A and 7B are process cross-sectional views showing a method of manufacturing a semiconductor device according to an example of the invention; and

FIG. 8 is a schematic view illustrating a cross-sectional structure of a relevant part of a semiconductor device manufactured according to the invention.

### DETAILED DESCRIPTION

Embodiments of the invention will now be described with reference to the drawings.

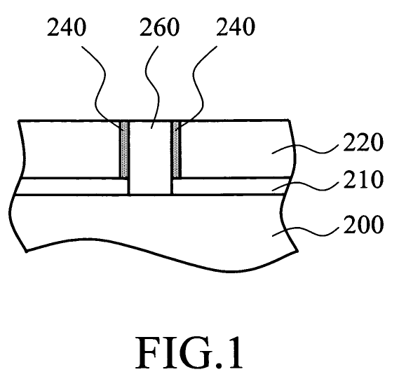

FIG. 1 is a schematic view illustrating a cross-sectional structure of a relevant part of a semiconductor device according to an embodiment of the invention.

More specifically, the semiconductor device according to the present embodiment comprises a semiconductor substrate 200 where semiconductor components and the like are formed. On the semiconductor substrate 200, a first film 210 and a low-k film 220 are formed in this order, through which a metallic wiring (or contact, via, etc.) 260 penetrates.

A protection layer 240 is provided on the sidewall of the low-k film220 adjacent to the metallic wiring 260. As described later in detail, the protection layer 240 is formed by forming a hole for the metallic wiring 260 in the low-k film 220 and then sputtering the underlying first film 210. This formation by sputtering allows formation of the protection layer 240 that has more compact film quality than the low-k film 220. When the first film 210 is made of material different in kind from the low-k film 220, the protection layer 240 includes elements that are not contained in the low-k film 220 but are contained in the first film 210.

The protection layer 240 thus formed contains as appropriate, for example, Si (silicon), C (carbon) , N (nitrogen), O (oxygen) and the like included in the first film 210, and typically has a thickness of 1 to 10 nanometers. This protection layer 240 avoids exposure of the sidewall of the low-k film 220, and avoids damage of the low-k film 220 even in treatments with various drug solution and plasma during the manufacturing process.

The first film 210 in the invention may include a thin film of silicon oxide (SiOₓ), silicon nitride (SiNₓ), silicon carbide (SiCₓ), silicon carboxide (SiCₓO_{y}), silicon oxinitride (SiOₓN_{y}), silicon carbonitride (SiCₓN_{y}) or the like. The protection layer 240 formed by sputtering such material is more compact than the low-k film 220 and has high physical and chemical durability. As a result, it can protect the sidewall of the hole of the low-k film 220 and reliably prevent introduction of damage.

The low-k film 220 may be made of materials including silicon oxides having methyl group(s), silicon oxides having hydrogen group(s), and organic polymers. Such materials may include, for example, various silsesquioxane compounds such as porous methyl silsesquioxane (MSQ), polyimide, fluorocarbon, parylene, and benzocyclobutene. The method of forming such materials may include the spin on glass (SOG) method in which a thin film is formed by spin coating and heat treating the solution.

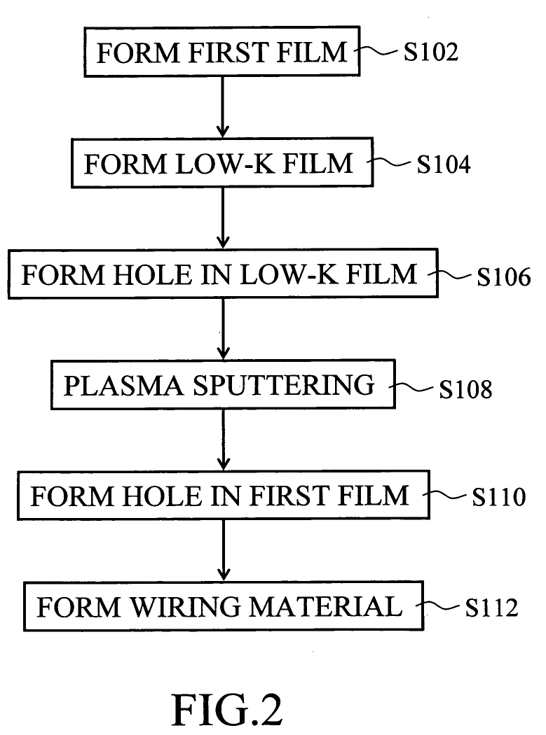

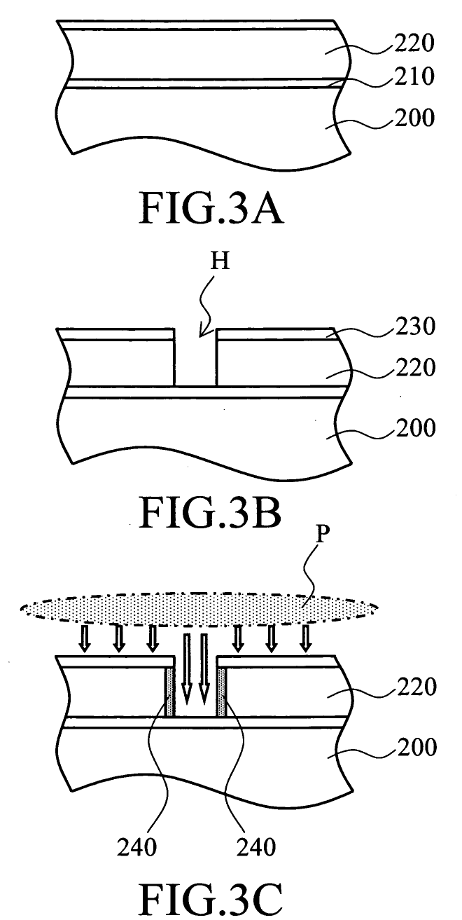

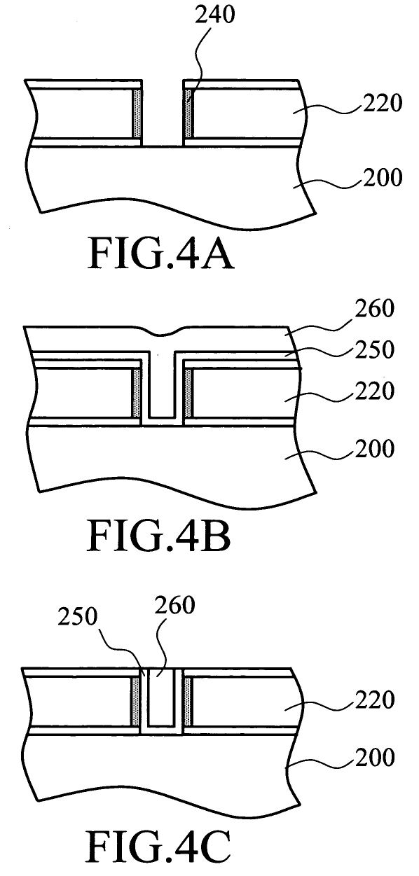

FIG. 2 is a flow chart showing the method of manufacturing a semiconductor device according to the present embodiment. FIGS. 3A through 3C and 4A through 4C are a process cross-sectional view showing a relevant part of the manufacturing method according to the present embodiment.

First, as shown in FIGS. 2 (step S102) and 3A, a first film 210 is formed on a semiconductor substrate 200. The semiconductor substrate 200 may have predetermined semiconductor components and electrodes formed thereon as appropriate. As described above, the first film 210 maybe made of various materials including silicon carbide and silicon nitride as appropriate.

Next, as shown in FIG. 2 (step S104), a low-k film 220 is formed. A second film 230 is then formed on the low-k film 220. While the invention does not necessarily require the second film 230, it is desirable to provide the second film 230 in order to protect the low-k film 220 during the sputtering treatment described below. The second film 230 may be made, for example, of the same kind of materials as the first film 210.

Next, as shown in FIGS. 2 (step S106) and 3B, a hole H is formed in the low-k film 220. At this time, the second film 230 can be used as a hard mask.

Subsequently, as shown in FIGS. 2 (step S108) and 3C, plasma P is applied. Plasma P may be generated from gas such as argon (Ar), hydrogen (H₂), and nitrogen (N₂). Exposure to plasma P allows the underlying first film 210 to be sputtered, which forms a protection layer 240 on the sidewall of the hole H in the low-k film 220. When the first film 210 is formed, for example, from silicon carbide (SiCₓ) or silicon nitride (SiNₓ), these materials are sputtered by plasma to form a protection layer 240 that contains silicon (Si), carbon (C), and nitrogen (N) as appropriate. The protection layer 240 made of these materials is more compact, and physically and chemically stabler than the low-k film 220. As a result, the low-k film 220 can be protected against various drug solution and plasma.

In addition, the second film 230 can protect the low-k film 220 against plasma P and prevent introduction of damage. Furthermore, the second film 230 around the hole H is also sputtered and deposited on the sidewall of the low-k film 220. That is, the second film 230 also contributes to the formation of the protection film 240. It is desirable also from this viewpoint that the second film 230 be formed from the same kind of materials as those of the first film 210.

Subsequently, as shown in FIGS. 2 (step S110) and 4A, a hole is provided in the first film 210. More specifically, a through-hole communicated with the hole H formed in the low-k film 220 is provided. It should be noted that the first film 210 exposed at the bottom of the hole H may be completely etched away by the plasma sputtering described above with reference to FIG. 3C. In this case, the process of further etching the first film 210 is not required.

Next, as shown in FIGS. 2 (step S112) and 4B, barrier metal 250 and wiring material 260 are deposited as appropriate. Then, as shown in FIG. 4C, embedding of wiring material is completed by planarization by CMP (chemical mechanical polishing).

As described above, according to the present embodiment, the low-k film 220 can be protected by the protection layer 240, which is formed by forming a hole H in the low-k film 220 and then sputtering the first film 210 exposed at the bottom of the hole H with plasma. As a result, the low-k film 220 can be protected against various drug solution and plasma during subsequent process steps, thereby preventing the shape distortion of the hole H and the degradation of the low-k film 220.

The embodiment of the invention will now be described in more detail with reference to an example.

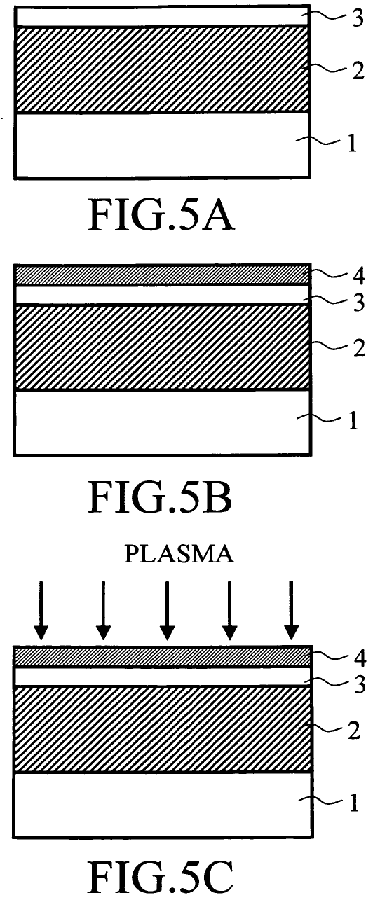

FIGS. 5A through 5C to 7A through 7B are a process cross-sectional view showing a method of manufacturing a semiconductor device according to an example of the invention.

First, as shown in FIG. 5A, a silicon wafer 1 is coated with a silicon oxide film 2 acting as an insulating film to a thickness of 500 nm. The silicon oxide film 2 is coated with a first film 3 comprising silicon nitride (SiNₓ) or silicon carbide (SiCₓ) having a thickness of about 30 to 50 nm by CVD (chemical vapor deposition) method. While the first film 3 is used later for forming a protection layer, it also acts as an etching stopper. More specifically, the first film 3 functions to control the etching of a subsequently formed low-k film to prevent the etching from progressing to its underlying layer. For this purpose, it is desirable that the first film 3 be formed from material having a lower etching rate than the low-k film by a factor of about 10 to 20.

Next, as shown in FIG. 5B, an adhesion enhancement layer 4 for enhancing adhesiveness to the low-k film that will be subsequently formed thereon is formed to a thickness of about 10 to 50 nm by the coating method. The material for the adhesion enhancement layer 4 in this specific example may include silicon oxides containing methyl group(s) . This material is coated at a rotation speed of 500 rpm and cured at a temperature of about 450° C.

Next, as shown in FIG. 5C, the surface of the adhesion enhancement layer 4 is plasma treated. More specifically, it is exposed to plasma of helium (He) gas, nitrogen oxide (N₂O) gas or hydrogen (H₂) gas under the condition of a power of 1 kW, a pressure of 1 kPa, and a temperature of 400° C. for about 15 to 30 seconds. Then the surface of the adhesion enhancement layer 4 has an increased roughness, and is turned into a hydrophobic surface to form a modified layer. The modified layer can increase the adhesion strength of the low-k film formed thereon and suppress the problems of film peeling and degradation due to water penetration.

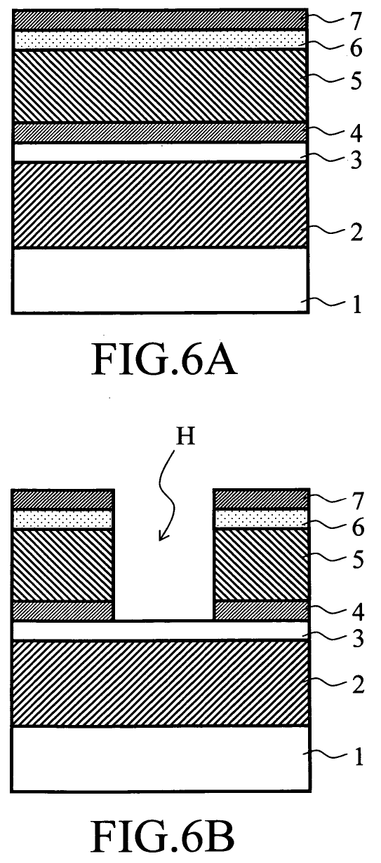

Subsequently, as shown in FIG. 6A, a MSQ film 5 having pores is formed to a thickness of 250 nm by the coating method. A silicon oxide film 6 is further formed thereon by CVD method. The low-k film 5 was made of material having a dielectric constant of 2.2 and a Young's modulus of 3 GPa. The low-k film 5 was formed by carrying out coating at a rotation speed of 900 rpm, then baking on the hot plate in N₂ atmosphere at a temperature of 250° C., and finally curing on hot plate at a temperature of 450° C. for 10 minutes.

Further, a second film 7 is formed thereon by depositing SiC by CVD method.

Next, as shown in FIG. 6B, a hole H is formed. More specifically, a hole is formed in the second film 7 by lithography and etching processes. This is used as a hard mask to etch the underlying silicon oxide film 6, low-k film 5, and adhesion enhancement layer 4.

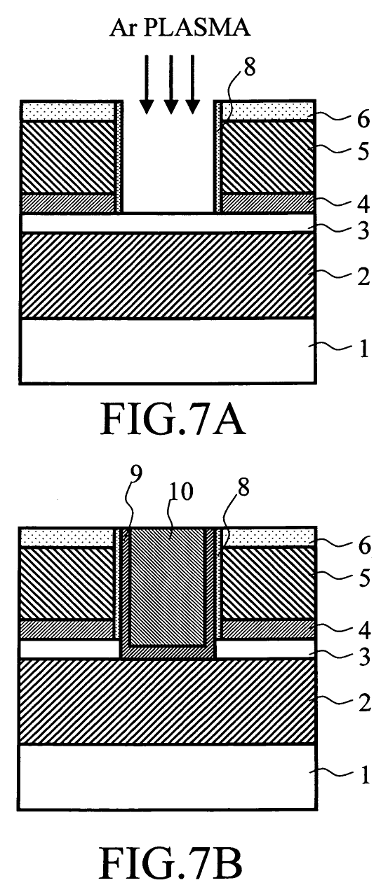

Subsequently, as shown in FIG. 7A, the underlying first film 3 is sputtered by Ar plasma to form a protection layer 8 on the sidewall of the hole H. At this time, Ar plasma is generated, for example, with a source power of 550 W and a bias power of 600 W. This allows a compact protection layer 8 containing Si (silicon) and C (carbon) to be formed on the sidewall of the hole with a thickness of about 1 to 10 nanometers.

Subsequently, as shown in FIG. 7B, a metallic wiring is formed. More specifically, CF₄ gas plasma is used to simultaneously etch the first film (SiC) 3 remaining at the bottom of the hole H and the second film (SiC) 7 exposed on the upper surface of the wafer.

Subsequently, the sputtering method is used to continuously deposit a film stack 9 composed of a tantalum nitride (TaN) film of 10 nm, a tantalum (Ta) film of 15 nm, and a seed copper (Cu) film of 65 nm. Then the electroplating method is used to form a copper film 10 of 500 nm, and the CMP method is used to polish Cu, Ta, and TaN except the groove, thereby forming a metallic wiring in the groove portion.

In the present example, as described above with reference to FIG. 7A, after a hole H is formed, the protection layer 8 is formed by sputtering the first film 3 with argon plasma, thereby enabling protection of the low-k film 5. Consequently, this can eliminate the problems of damage and hole shape distortion during subsequent processes, or the degradation of the semiconductor device due to water penetration through the sidewall of the hole.

In addition, in the present example, as described above with reference to FIG. 5C, the surface of the adhesion enhancement layer 4 is exposed to plasma P to form a modified layer, thereby increasing the adhesion strength of the low-k film 5. As a result, the problem of peeling of the low-k film 5 can also be eliminated during the polishing process by the CMP method described above with reference to FIG. 7B.

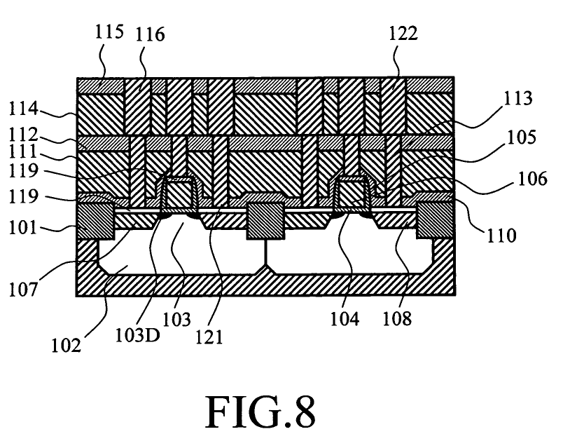

FIG. 8 is a schematic view illustrating a cross-sectional structure of a relevant part of a semiconductor device manufactured according to the invention. More specifically, this figure shows a relevant part of a MOSFET (Metal Oxide Semiconductor Field Effect Transistor) that constitutes a semiconductor integrated circuit.

The surface portion of the silicon substrate is isolated and separated by component separation regions 101, and a MOSFET is formed in each of the separated wells 102. Each MOSFET comprises a source region 107, a drain region 108, and a channel 103 provided between them. A gate electrode 106 is provided on the channel 103 via a gate isolation film 104. LDD (lightly doped drain) regions 103D are provided between the source/drain region 107, 108 and the channel 103 for the purpose of preventing the so-called “short channel effect”. A gate sidewall 105 is provided adjacent to the gate electrode 106 on the LDD region 103D. The gate sidewall 105 is provided in order to form the LDD region 103D in a self-aligned manner.

Silicide layers 119 are provided on the source/drain region 107, 108 and the gate electrode 106 for improving contact with the electrode. The upper side of this structure is covered with a first interlayer isolation film 110, a second interlayer isolation film 111 and a third interlayer isolation film 112, through which contact holes penetrate. Source contact 113S, gate contact 113G, and drain contact 113D are formed through the contact holes. Here, the first interlayer isolation film 110 and the third interlayer isolation film 112 act as an etching stopper, and can be formed from silicon nitride, for example. The second interlayer isolation film 111 may be, for example, a low-k film made of porous silicon oxide.

Further thereon, a fourth interlayer isolation film 114 and a fifth interlayer isolation film 115 are formed. In trenches penetrating through them, source wiring 116S, gate wiring 116G, and drain wiring 116D are each embedded. Here, the fourth interlayer isolation film 114 may also be a low-k film made of porous silicon oxide. The fifth interlayer isolation film 115 may be formed from silicon nitride.

A protection layer 121 is provided between the source contact 113S, gate contact 113G, and drain contact 113D formed through the contact holes, and the second interlayer isolation film (low-k film) 111. Similarly, a protection layer 122 is provided between the source wiring 116S, gate wiring 116G and drain wiring 116D, and the fourth interlayer isolation film (low-k film) 114 as well.

The protection layer 121 can be formed by forming contact holes for the source contact 113S, gate contact 113G, and drain contact 113D, and then sputtering the first interlayer isolation film 110 exposed at the bottom of the holes with plasma.

The protection layer 122 can be formed by forming holes for the source wiring 116S, gate wiring 116G, and drain wiring 116D, and then sputtering the third interlayer isolation film 112 exposed at the bottom of the holes with plasma.

The protection layers 121 and 122 can protect the interlayer isolation films 111 and 114 made of low-k material, and prevent degradation due to drug solution and plasma during the manufacturing process, and hole shape distortion. It can also suppress degradation of the semiconductor device due to water penetration between the films.

The embodiments of the invention have been described with reference to specific examples. However, the invention is not limited to these specific examples.

For example, any specific structure, size, and material of the semiconductor device, including their variations appropriately modified and adapted by those skilled in the art, are encompassed within the scope of the invention, as long as they include the features of the invention.

Any formation method, formation condition, processing condition, etching condition, and heat treatment condition for various layers, not only described above by specific examples, but also their variations appropriately designed by those skilled in the art, are encompassed within the scope of the invention.

Furthermore, any other methods of manufacturing a semiconductor device that comprise the elements of the invention and that may be appropriately modified by those skilled in the art are encompassed within the scope of the invention.

While the present invention has been disclosed in terms of the embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

1. A semiconductor device comprising:
a substrate;
a first film provided on the substrate;
an insulation layer made of low-k material provided on the first film;
a protection layer provided on a sidewall of a hole penetrating through the insulation layer and the first film to the substrate to cover the insulation layer, the protection layer being more compact than the low-k material; and
a conducting portion filling the hole.

2. The semiconductor device as claimed in claim 1, wherein the protection layer is formed to cover the insulation layer of the sidewall of the hole by sputtering the first film with plasma when the first film appears at the bottom of the hole before the hole is allowed to penetrate through the insulation layer and the first film to the substrate.

3. The semiconductor device as claimed in claim 1, further comprising a second film provided on the insulation layer and formed from the same kind of material as the first film.

4. The semiconductor device as claimed in claim 1, wherein the first film comprises as a main ingredient at least one selected from the group consisting of silicon oxide (SiOₓ), silicon nitride (SiNₓ), silicon carbide (SiCₓ), silicon carboxide (SiCₓO_{y}), silicon oxinitride (SiOₓN_{y}), and silicon carbonitride (SiCₓN_{y}).

5. The semiconductor device as claimed in claim 1, wherein the low-k material comprises as a main ingredient at least one selected from the group consisting of silicon oxides having one or more methyl groups, silicon oxides having one or more hydrogen groups, and organic polymers.

6. A semiconductor device comprising:
a substrate;
a first film provided on the substrate;
an insulation layer made of low-k material provided on the first film;
a protection layer provided on a sidewall of a hole penetrating through the insulation layer and the first film to the substrate to cover the insulation layer, the protection layer containing one or more elements that are included in the first film but are not included in the low-k material; and
a conducting portion filling the hole.

7. The semiconductor device as claimed in claim 6, wherein the protection layer is formed to cover the insulation layer of the sidewall of the hole by sputtering the first film with plasma when the first film appears at the bottom of the hole before the hole is allowed to penetrate through the insulation layer and the first film to the substrate.

8. The semiconductor device as claimed in claim 6, further comprising a second film provided on the insulation layer and formed from the same kind of material as the first film.

9. The semiconductor device as claimed in claim 6, wherein the first film comprises as a main ingredient at least one selected from the group consisting of silicon oxide (SiOₓ), silicon nitride (SiNₓ), silicon carbide (SiCₓ), silicon carboxide (SiCₓO_{y}), silicon oxinitride (SiOₓN_{y}), and silicon carbonitride (SiCₓN_{y}).

10. The semiconductor device as claimed in claim 6, wherein the low-k material comprises as a main ingredient at least one selected from the group consisting of silicon oxides having one or more methyl groups, silicon oxides having one or more hydrogen groups, and organic polymers.

11. A method of manufacturing a semiconductor device comprising the steps of:
forming a first film on a substrate;
forming an insulation layer made of low-k material on the first film;
forming a hole penetrating through the insulation layer to the first film;
sputtering the first film exposed at the bottom of the hole with plasma to form a protection layer on a sidewall of the hole; and
filling the hole with conductive material.

12. The method of manufacturing a semiconductor device as claimed in claim 11, wherein the plasma is formed using at least one gas selected from the group consisting of argon (Ar), hydrogen (H₂), and nitrogen (N₂).

13. The method of manufacturing a semiconductor device as claimed in claim 11, wherein the first film comprises as a main ingredient at least one selected from the group consisting of silicon oxide (SiOₓ), silicon nitride (SiNₓ), silicon carbide (SiCₓ), silicon carboxide (SiCₓO_{y}), silicon oxinitride (SiOₓN_{y}), and silicon carbonitride (SiCₓN_{y}).

14. The method of manufacturing a semiconductor device as claimed in claim 11, wherein the low-k material comprises as a main ingredient at least one selected from the group consisting of silicon oxides having one or more methyl groups, silicon oxides having one or more hydrogen groups, and organic polymers.

15. The method of manufacturing a semiconductor device as claimed in claim 11, wherein the protection layer is more compact than the low-k material.

16. A method of manufacturing a semiconductor device comprising the steps of:
forming a first film on a substrate;
forming an insulation layer made of low-k material on the first film;
forming a second film on the insulation layer;
forming a hole penetrating through the second film and the insulation layer to the first film;
sputtering the first film exposed at the bottom of the hole with plasma to form a protection layer on a sidewall of the hole; and
filling the hole with conductive material.

17. The method of manufacturing a semiconductor device as claimed in claim 16, wherein the second film is made of the same kind of material as the first film.

18. The method of manufacturing a semiconductor device as claimed in claim 16, wherein the plasma is formed using at least one gas selected from the group consisting of argon (Ar), hydrogen (H₂), and nitrogen (N₂).

19. The method of manufacturing a semiconductor device as claimed in claim 16, wherein the first film comprises as a main ingredient at least one selected from the group consisting of silicon oxide (SiOₓ), silicon nitride (SiNₓ), silicon carbide (SiCₓ), silicon carboxide (SiCₓO_{y}), silicon oxinitride (SiOₓN_{y}), and silicon carbonitride (SiCₓN_{y}).

20. The method of manufacturing a semiconductor device as claimed in claim 16, wherein the low-k material comprises as a main ingredient at least one selected from the group consisting of silicon oxides having one or more methyl groups, silicon oxides having one or more hydrogen groups, and organic polymers.
